(19) United States
(12) Patent Application Publication
(10) Pub. No.: US 2022/0086961 A1
(43) Pub. Date: Mar. 17, 2022

(54) TRANSPARENT THIN FILM HEATER WITH GOOD MOISTURE TOLERANCE AND MECHANICAL PROPERTIES COMPRISING A TRANSPARENT CONDUCTING OXIDE AND THE METHOD FOR PRODUCING THE SAME

(71) Applicant: KOREA INSTITUTE OF SCIENCE AND TECHNOLOGY, Seoul (KR)

(72) Inventors: Ji-Won CHOI, Seoul (KR); Jin Sang KIM, Seoul (KR); Chong Yun KANG, Seoul (KR); Seung Hyub BAEK, Seoul (KR); Seong Keun KIM, Seoul (KR); Hyun-Cheol SONG, Seoul (KR); Jungho YOON, Seoul (KR); Joohee JANG, Seoul (KR)

(21) Appl. No.: 17/475,346

(22) Filed: Sep. 15, 2021

(30) Foreign Application Priority Data
Sep. 17, 2020 (KR) 10-2020-0119922

(51) Int. Cl. H05B 3/86; C23C 14/08; C23C 14/24; H05B 3/14

(52) U.S. Cl. CPC H05B 3/86; C23C 14/086; H05B 2203/017; H05B 3/141; H05B 2203/013; C23C 14/24

(57) ABSTRACT

The present disclosure provides a transparent thin film heater including: a metal layer; and a transparent conductive oxide layer, wherein the transparent conductive oxide layer includes a composition represented by the following Chemical Formula 1 and is doped with nitrogen:

ZnₓSn₁₋ₓO₂ [Chemical Formula 1]
wherein 0<x≤0.12.

### CROSS-REFERENCE TO RELATED APPLICATION

This application claims priority to Korean Patent Application No. 10-2020-0119922, filed on Sep. 17, 2020, and all the benefits accruing therefrom under 35 U.S.C. § 119, the contents of which in its entirety are herein incorporated by reference.

### TECHNICAL FIELD

The present disclosure relates to a transparent thin film heater including a transparent conductive oxide and a method for manufacturing the same.

### BACKGROUND ART

Transparent conductive oxides (TCOs) show a high transmittance (>80%) and low resistivity (<10⁻⁴ Ω·cm) in the visible light region and are used as transparent electrodes in various devices, such as touch panels, solar cells, displays, or the like. Recently, transparent conductive oxides are used as transparent thin film heaters (TFHs) for car windows, airplane displays, LCD panels, or the like. The transparent thin film heater using a transparent conductive oxide is a kind of sheet-type heating element, generates heat through the Joule heating mode and can remove fogging and frost on car or airplane windows. Currently, ITO, which is a transparent oxide, is used frequently for transparent thin film heaters. However, ITO requires a processing temperature of 300° C. or higher to cause a difficulty in use of a flexible substrates, has brittleness to cause a limitation in application to flexible electronic devices, and causes an increase in costs required for manufacturing transparent thin film heaters due to the scarcity of indium.

There have been conducted studies about flexible transparent electrode materials which can solve the above-mentioned problems of ITO, satisfy the quality of ITO or higher quality and can be applied to various flexible devices and thin film heaters. Among the flexible transparent electrode materials that have been studied currently, oxide/metal/oxide multilayer structures are those formed by inserting a thin metal film between oxide layers, have conductivity next to the conductivity of metals, and can show high transmittance by virtue of an anti-reflection effect derived from a difference in refractive index between a metal layer and an oxide layer.

In addition, since such multilayer thin films are processed totally at room so temperature, they can be applied to flexible substrates with ease and have flexibility by virtue of a ductile metal layer interposed between oxide layers. When such oxide/metal/oxide multilayer thin films having excellent electrical and optical properties are applied to transparent thin film heaters, the transparent thin film heaters can be driven at a low voltage, consume lower electric power as compared to the conventional heating wires installed for removing fogging and frost on car windows, and thus can save energy. Further, opaque heating wires cannot be used for the front surfaces of car windscreens, but the oxide/metal/oxide multilayer thin films having high transmittance can be used for rear windows as well as car windscreens, while not blocking the view.

However, silver (Ag) used typically for a metal layer of multilayer thin films undergoes degradation of electrical and optical properties at high temperature or humidity due to severe diffusion or oxidation of Ag, and thus is to problematic in that the transparent thin film heaters using the multilayer thin films may also undergo degradation of performance.

### DISCLOSURE

### Technical Problem

A technical problem to be solved by the present disclosure is to provide a transparent thin film heater having a multilayer structure, ensuring moisture tolerance and thermal stability, showing a high response rate and high-temperature stability, and consuming low electric power.

### Technical Solution

In one general aspect, there is provided a transparent thin film heater including: a metal layer; and a transparent conductive oxide layer, wherein the transparent conductive oxide layer has a composition in which the following Chemical Formula 1 is doped with nitrogen:

ZnₓSn₁₋ₓO₂ [Chemical Formula 1]

wherein 0<x≤0.12.

According to an embodiment, the transparent thin film heater may include a multilayer structure of transparent conductive oxide layer/metal layer/transparent conductive oxide layer (OMO) or a multilayer structure of metal layer/transparent conductive oxide layer (MO).

According to an embodiment, the metal layer may have a thickness of 5-25 nm.

According to an embodiment, the metal layer may have a thickness of 8-15 nm.

According to an embodiment, the transparent conductive oxide layer may have a thickness of 20-80 nm.

According to an embodiment, the transparent conductive oxide layer may be formed through vapor deposition under gas atmosphere of argon (Ar), oxygen (O₂) and nitrogen (N₂).

According to an embodiment, the transparent conductive oxide layer may be doped with nitrogen under gas atmosphere with a partial pressure of so nitrogen of 0.1-2.0%.

According to an embodiment, the transparent thin film heater may be a flexible transparent thin film heater.

According to an embodiment, the transparent thin film heater may further include a connection unit configured to apply electric voltage to the transparent thin film heater, and may have an applied voltage of 1-10 V.

According to an embodiment, the transparent thin film heater may reach a temperature of 100° C. within 30 seconds, when a voltage of 6 V or less is applied to the transparent thin film heater.

In another general aspect, there is provided a transport means including the transparent thin film heater.

In still another general aspect, there is provided a smart window including the transparent thin film heater.

In yet another general aspect, there is provided a method for manufacturing a transparent thin film heater, including a step of carrying out vapor deposition of a transparent conductive oxide layer on either surface or both surfaces of a metal layer, wherein the transparent conductive oxide layer has a composition in which the following Chemical Formula 1 is doped with nitrogen:

ZnₓSn₁₋ₓO₂ [Chemical Formula 1]

wherein 0<x≤0.12.

According to an embodiment, the step of carrying out vapor deposition may be performed under vapor deposition gas atmosphere including nitrogen so (N₂), and at least one of argon (Ar) and oxygen (O₂).

According to an embodiment, the vapor deposition may be physical vapor deposition (PVD).

According to an embodiment, the vapor deposition gas may have a partial pressure represented by the following Mathematical Formulae 1 and 2:

[O₂/(Ar+O₂+N₂)]=X [Mathematical Formula 1]

[N₂/(Ar+02+N₂)]=Y [Mathematical Formula 2]

wherein 0<X≤0.01, and 0<Y<0.02.

According to an embodiment, the vapor deposition gas may have a partial pressure of nitrogen of 0.1-2.0%.

According to an embodiment, the transparent conductive oxide layer is vapor-deposited on both surfaces of the metal layer on a substrate.

According to an embodiment, the substrate may be at least one selected from the group consisting of substrates including polyethylene terephthalate, polyether sulfone, polycarbonate or a polymer thereof.

### Advantageous Effects

The transparent thin film heater according to an embodiment of the present disclosure includes a multilayered transparent conductive thin film based on Zn-doped SnOₓ doped with nitrogen and having excellent moisture tolerance and thermal stability, and thus allows heating at a high response rate even under a relatively low operating voltage and can provide stable cycle characteristics.

### BRIEF DESCRIPTION OF DRAWINGS

FIG. 1 is a schematic view illustrating the method for manufacturing a transparent thin film heater according to an embodiment of the present disclosure, wherein the transparent thin film heater is manufactured by using a physical vapor deposition (on-axis RF magnetron sputtering) process, while controlling partial pressure of atmosphere gas.

FIG. 2 illustrates the transparent thin film heater according to an embodiment of the present disclosure, wherein a connection unit configured to apply electric voltage is connected thereto.

FIG. 3A and FIG. 3B show the results of a constant temperature-constant humidity test for a sample using a transparent conductive oxide layer including nitrogen-doped Zn—SnOₓ and a sample using a transparent conductive oxide layer including Zn—SnOₓ not doped with nitrogen, as the transparent thin film heater according to an embodiment of the present disclosure, in terms of the sheet resistance and transmittance values of each multilayer thin film measured every 10 hours.

FIG. 4 shows the temperature behavior of the transparent thin film heater according to an embodiment of the present disclosure, as a function of voltage.

FIG. 5 shows the cycle characteristics of a sample using a transparent conductive oxide layer including nitrogen-doped Zn—SnOₓ, as compared to those of a sample using a transparent conductive oxide layer including Zn—SnOₓ not doped with nitrogen, as the transparent thin film heater according to an embodiment of the present disclosure.

FIG. 6 shows the results of a moisture removal test for the transparent thin film heater according to an embodiment of the present disclosure.

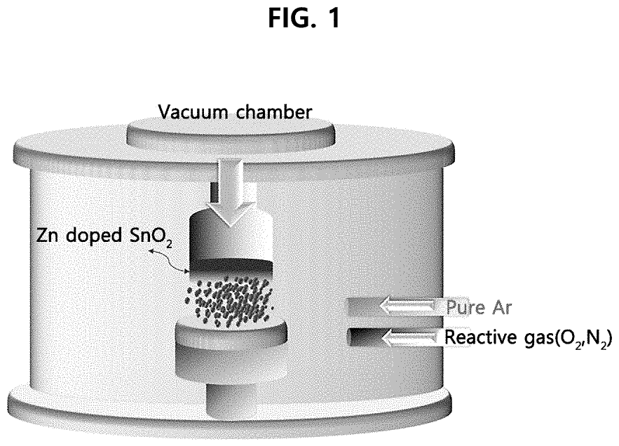

### BEST MODE

Exemplary embodiments now will be described more fully hereinafter.

This disclosure may, however, be embodied in many different forms and should not be construed as limited to the exemplary embodiments set forth therein.

Since various changes and modifications within the scope of the disclosure will become apparent to those skilled in the art from this detailed description, the scope of the present disclosure is not limited to any specific embodiments. It should be understood that other equivalents and modifications could be made without departing from the scope of the disclosure.

Transparent Thin Film Heater

To solve the above-mentioned problems, the inventors of the present disclosure have conducted intensive studies to obtain a transparent thin film heater using Zn-doped SnOₓ doped with nitrogen and having moisture tolerance at high temperature and high humidity, and have found that the transparent thin film heater undergoes a rapid increase in temperature to 100° C. at a relatively low voltage and shows stable cycle characteristics. The present disclosure is based on this finding.

In one aspect of the present disclosure, there is provided a transparent thin film heater including: a metal layer; and a transparent conductive oxide layer, wherein the transparent conductive oxide layer may have a composition in which the following Chemical Formula 1 is doped with nitrogen:

ZnₓSn₁₋ₓO₂ [Chemical Formula 1]

wherein 0<x≤0.12.

According to an embodiment, the transparent conductive oxide layer may be crystallized at high temperature, may have an amorphous phase at room temperature, and may show excellent chemical stability and high strength.

According to an embodiment, the transparent conductive oxide layer may be a nitrogen-doped layer including a composition of zinc (Zn)-doped SnO₂ as shown in Chemical Formula 1. Particularly, the composition of Chemical Formula 1 is derived by substituting Sn ion of SnO₂ with Zn, a transition metal, and may have excellent electrical and optical properties within a specific range of composition, even when being vapor-deposited at room temperature.

For example, x may be 0.12 or less. When x is larger than 0.12 in the composition of ZnₓSn₁₋ₓO₂ represented by Chemical Formula 1, it is difficult to realize excellent temperature behavior and cycle characteristics to be accomplished by the embodiments of the present disclosure. Preferably, x may satisfy 0.01<x≤0.1, and it is possible to realize excellent temperature behavior and cycle characteristics within the above-defined range. For example, x may be 0.045 (2.43 wt %), and it is possible to realize optimized temperature behavior and cycle characteristics in this case.

According to an embodiment, the transparent conductive oxide layer may include a nitrogen-doped composition of Chemical Formula 1, i.e. nitrogen-doped Zn—SnOₓ layer. It is possible to obtain a transparent thin film heater which not only ensures excellent moisture tolerance and thermal stability but also has a high response rate, is stable even at high temperature and requires low electric power consumption, through the nitrogen doping. In addition, the thin film may have increased density through the nitrogen doping, resulting in improvement of stability and cycle characteristics against high temperature and moisture, and hardness.

Meanwhile, when the transparent conductive oxide layer is exposed continuously to a high temperature and/or high humidity condition, it may undergo degradation of performance. The stability depending on temperature and/or humidity may be improved by doping the transparent conductive oxide layer with nitrogen.

Meanwhile, the sheet resistance characteristics may be degraded, when the transparent conductive oxide layer is exposed continuously to a high temperature and/or high humidity condition. The stability depending on temperature and/or humidity may be improved by doping the transparent conductive oxide layer with nitrogen.

For example, when the transparent conductive oxide layer doped with nitrogen under gas atmosphere with a partial pressure of nitrogen of 0.1-2.0%, it can retain its characteristics, even after being exposed to a temperature and/or humidity condition (e.g. 65-90% RH condition) for about 60 hours, and thus can provide stability against high temperature and moisture through the nitrogen so doping.

In general, a metal layer or metal thin film has high electrical conductivity but shows a low light refractive index and high light reflectivity. Therefore, a layer including a metal thin film alone may show poor light transmittance. On the other hand, the multilayered transparent conductive oxide thin film has a multilayer structure including transparent conductive oxide layers disposed at the top and bottom of a metal layer, and thus generates an anti-reflection effect from the metal layer so that the light propagation properties in a medium may be changed to inhibit reflection from the metal layer and to increase transmittance.

According to an embodiment, the metal in the metal layer may include at least one metal selected from Ag, Au, Cu, Pd, Pt, Ni, Al, Y, La, Mg, Ca, Fe, Pb, Zn, and alloys thereof. Preferably, the metal may include Ag showing significantly low light absorption in the visible region and low resistivity, as compared to the other metals.

According to an embodiment, the transparent thin film heater may include a multilayer structure of transparent conductive oxide layer/metal layer/transparent conductive oxide layer (OMO) or a multilayer structure of metal layer/transparent conductive oxide layer (MO). Preferably, the transparent thin film heater may have a multilayer structure of transparent conductive oxide layer/metal layer/transparent conductive oxide layer (OMO).

According to an embodiment, the metal layer may have a thickness of 5-25 nm. Particularly, the metal layer may have a thickness of 8-25 nm, 12-25 nm, 12-20 nm, 8-15 nm, or 12-15 nm. For example, when the metal layer has so an excessively small thickness of less than 5 nm, it is difficult to form a uniform film of metal layer, and the sheet resistance of the transparent conductive oxide layer may be increased to cause degradation of electrical properties. In addition, when the metal layer has a thickness of larger than 25 nm, it shows low transmittance, and thus may not be used as a metal layer in a multilayer structure.

According to an embodiment, the transparent conductive oxide layer may have a thickness of 20-80 nm. For example, when the transparent conductive oxide layer has a thickness of less than 20 nm or larger than 80 nm, it is not possible to realize an anti-reflection effect from the metal layer, resulting in degradation of transmittance.

In a non-limiting embodiment, the metal layer may have a thickness of 5-25 nm and the transparent conductive oxide layer may have a thickness of 20-80 nm, preferably. More preferably, the metal layer may have a thickness of 12-20 nm, and the transparent conductive oxide layer may have a thickness of 30-50 nm. Meanwhile, for the purpose of uniform heat distribution in the transparent thin film heater after heating, the metal layer should be grown in the form of a uniform thin film. In this case, it is required for the metal layer to have a thickness of 12 nm or more. Herein, when the transparent conductive oxide layer has a thickness of 30-50 nm, it is possible to realize the highest transmittance by virtue of an anti-reflection effect from the metal layer.

According to an embodiment, the transparent conductive oxide layer may be formed through vapor deposition under gas atmosphere including nitrogen (N₂), and at least one of argon (Ar) and oxygen (O₂). For example, the transparent conductive oxide layer may be formed through vapor deposition under gas atmosphere of argon (Ar), oxygen (O₂) and nitrogen (N₂). Therefore, a Zn-doped SnOₓ thin film may be vapor-deposited by using a gas partial pressure condition (Ar, O₂, N₂) ensuring moisture tolerance and thermal stability. In this manner, it is possible to realize excellent electrical and optical properties and to provide thermal stability and moisture tolerance.

According to an embodiment, the transparent conductive oxide layer may be doped with nitrogen under gas atmosphere with a partial pressure of nitrogen of 0.1-2.0%. When the partial pressure of nitrogen is less than 0.1%, it is difficult to realize excellent stability against temperature and/or humidity and high hardness. When the partial pressure of nitrogen is larger than 2.0%, the sheet resistance and light transmittance characteristics of the thin film may be degraded. Preferably, when the partial pressure of nitrogen is 1.0% under vapor deposition gas atmosphere, it is possible to realize excellent electrical and optical properties and to provide thermal stability and moisture tolerance.

According to an embodiment, the transparent thin film heater may further include a substrate stacked on the transparent conductive oxide layer. Particularly, the transparent conductive oxide layer may be vapor-deposited on the substrate, and the vapor deposition may be carried out at room temperature. Therefore, the transparent conductive oxide layer may be vapor-deposited uniformly even on a heat-liable flexible plastic substrate which includes a polymer, such as polyethylene terephthalate (PET) or polycarbonate (PC), and may be deformed easily at a temperature of 150° C. or higher, as well as a glass substrate or a rigid substrate including polyethylene, polyester, or the like. For example, the substrate may include at least one polymer selected from polyethylene terephthalate, polyether sulfone and polycarbonate.

According to an embodiment, the transparent thin film heater may be a flexible transparent thin film heater, particularly a multilayered flexible transparent thin film heater that may be attached to glass in the form of a film. In this manner, the transparent thin film heater may be applied with ease in the field of smart windows for buildings, cars, or the like.

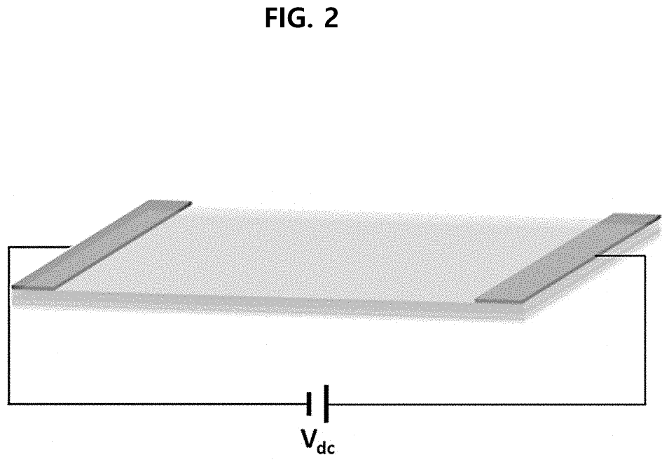

According to an embodiment, the transparent thin film heater may further include a connection unit configured to apply electric voltage to the transparent thin film heater, and may have an applied voltage of 1-16 V. Particularly, the connection unit may be disposed at both ends of the transparent thin film heater, as shown in FIG. 2. Electric voltage is applied to the transparent thin film heater through the connection unit, and the temperature of the transparent thin film heater may be increased rapidly at a low voltage.

According to an embodiment, the transparent thin film heater may reach a temperature of 100° C. within 30 seconds, when a voltage of 6 V or less is applied to the transparent thin film heater. For example, when a low voltage of 6V or less is applied, it is possible to provide a warming rate of 100° C./30 seconds. When the voltage applied to the transparent thin film heater is decreased, the time required for reaching the highest temperature is increased, and the highest temperature may be decreased. However, when an excessively high voltage is applied, the other parts of the transparent thin film heater may be deteriorated, the circuit stability may be affected adversely, and so the energy efficiency is reduced. Therefore, it is important for the transparent thin film heater to have high efficiency with low electric power consumption. Therefore, the transparent thin film heater according to an embodiment of the present disclosure may have a high response rate at a relatively low voltage and is stable even at high temperature.

In another aspect of the present disclosure, there is provided a transport means including the transparent thin film heater, Particularly, the transport means may include various transport means, such as cars, airplanes, or the like. The transparent thin film heater may be used, when the view in such transport means is interrupted due to the frost or fogging on the windows.

In still another aspect of the present disclosure, there is provided a smart window including the transparent thin film heater. The smart window may be a window having multiple functions, such as a display function of exhibiting various types of information, a function of controlling indoor temperature and a function as a heater capable of removing elements that may interrupt the view.

Method for Manufacturing Transparent Thin Film Heater

In yet another aspect of the present disclosure, there is provided a method for manufacturing a transparent thin film heater, including a step of carrying out vapor deposition of a transparent conductive oxide layer on either surface or both surfaces of a metal layer, wherein the transparent conductive oxide layer has a composition in which the following Chemical Formula 1 is doped with nitrogen:

ZnₓSn₁₋ₓO₂ [Chemical Formula 1]

wherein 0<x≤0.12.

Meanwhile, unlike the conventional indium tin oxide (ITO) vapor-deposited at a high temperature of about 200° C. or higher, the transparent conductive oxide having a specific composition represented by Chemical Formula 1 according to an embodiment of the present disclosure may be vapor-deposited at room temperature as an amorphous phase.

According to an embodiment, the step of carrying out vapor deposition may be performed under vapor deposition gas atmosphere including nitrogen (N₂), and at least one of argon (Ar) and oxygen (O₂). For example, the vapor deposition step may be carried out under vapor deposition gas atmosphere including nitrogen (N₂). In addition, the partial pressure of nitrogen (N₂) gas in the atmosphere gas may be controlled to control the hardness and/or to temperature and moisture stability of the transparent conductive oxide layer.

Particularly, the transparent conductive oxide layer may be formed by vapor-deposition of a deposition target (deposition source) including the transparent conductive oxide represented by Chemical Formula 1 on a substrate. Herein, the vapor deposition may be carried out by using various vapor deposition processes, such as sputtering, chemical vapor deposition (CVD), physical vapor deposition (PVD) processes, or the like, and the vapor deposition may be physical vapor deposition, preferably.

According to an embodiment, the vapor deposition gas may have a partial pressure represented by the following Mathematical Formulae 1 and 2:

[O₂/(Ar+O₂+N₂)]=X [Mathematical Formula 1]

[N₂/(Ar+O₂+N₂)]=Y [Mathematical Formula 2]

wherein O₂, Ar and N₂ represent the partial pressure of oxygen (O₂), argon (Ar) and nitrogen (N₂), respectively, 0<X≤0.01, and 0<Y<0.02.

For example, X may satisfy 0<X≤0.01, and Y may satisfy 0<Y<0.02, particularly 0<Y≤0.015, 0<Y≤0.01, 0.005<Y≤0.015, or 0.005≤Y≤0.01, preferably 0<Y<0.01. For example, when Y is larger than 0.02, it is difficult to maintain excellent electrical properties and high light transmittance. In addition, when the partial pressure of oxygen and nitrogen, X and Y, are not within the above-defined ranges, it is difficult to maintain excellent electrical properties and high light transmittance to be accomplished by the present disclosure. More preferably, when X is 0.003 and Y is 0.01, it is possible to realize excellent electrical and optical properties and to provide thermal stability and moisture tolerance.

According to an embodiment, the vapor deposition gas may have a partial pressure of nitrogen of 0.1-2.0%. When the transparent conductive oxide layer is vapor-deposited under vapor deposition gas atmosphere with a partial pressure of nitrogen of 0.1-2.0% and then doped with nitrogen, it can retain its characteristics, even after being exposed to a temperature and/or humidity condition (e.g. 65-90% RH condition) for about 60 hours, and thus can have stability against high temperature and moisture through the nitrogen doping.

According to an embodiment, the transparent conductive oxide layer is vapor-deposited on both surfaces of the metal layer on a substrate.

Therefore, the present disclosure provides a transparent thin film heater using Zn-doped SnOₓ doped with nitrogen and having not only excellent electrical and optical properties but also moisture tolerance and thermal stability. The transparent thin film heater according to the present disclosure may be operated at a high rate under a relatively low operating voltage and show stable cycle characteristics, and thus may be applied as a transparent thin film heater for cars, airplanes, or the like.

### EXAMPLES

Exemplary embodiments now will be described more fully hereinafter. The present disclosure may, however, be embodied in many different forms and should not be construed as limited to the exemplary embodiments set forth therein.

### Example 1: Multilayered Transparent Thin Film Heater Based on Zn-Doped SnOₓ Doped with Nitrogen

A multilayer structure of Zn—SnOₓ/Ag/Zn—SnOₓ including SnOₓ doped with 3 at % of zinc (Zn) was vapor-deposited on a PET substrate to obtain a transparent thin film heater.

The oxide layer (Zn—SnOₓ) of the multilayer thin film of Zn—SnOₓ/Ag/Zn—SnOₓ was vapor-deposited through an anon-axis RF magnetron sputtering process. Herein, the Zn—SnOₓ target was applied with a power of 10 W and so vapor-deposited under atmosphere with O₂/(Ar+02+N₂) of 0.3% and N₂/(Ar+02+N₂) of 1.0% at a work vacuum pressure of 5 mtorr. The Zn—SnO₂ thin films as the top and bottom oxide layers of the multilayered transparent conductive thin film were vapor-deposited to a thickness of 40 nm, and the Ag thin film was vapor-deposited to a thickness of 12 nm. Thus, the multilayered transparent conductive thin film had a total thickness of 92 nm.

### Example 2: Multilayered Transparent Thin Film Heater Based on Zn-Doped SnOₓ not Doped with Nitrogen

A transparent thin film heater was obtained in the same manner as Example 1, except that the vapor deposition was carried out under atmosphere with N₂/(Ar+02+N₂) of 0.0%.

### Test Example 1: High-Temperature and Moisture Stability

Based on the results of sheet resistance and transmittance depending on partial pressure of nitrogen, the stability of sheet resistance and light transmittance characteristics was tested with a maximum partial pressure of nitrogen of 1.0%. Particularly, Example 1 (partial pressure of nitrogen=1.0%) was compared with Example 2 (partial pressure of nitrogen=0.0%) under a constant temperature-constant humidity test condition of 65° C. and 90% RH to evaluate the stability against high temperature and moisture.

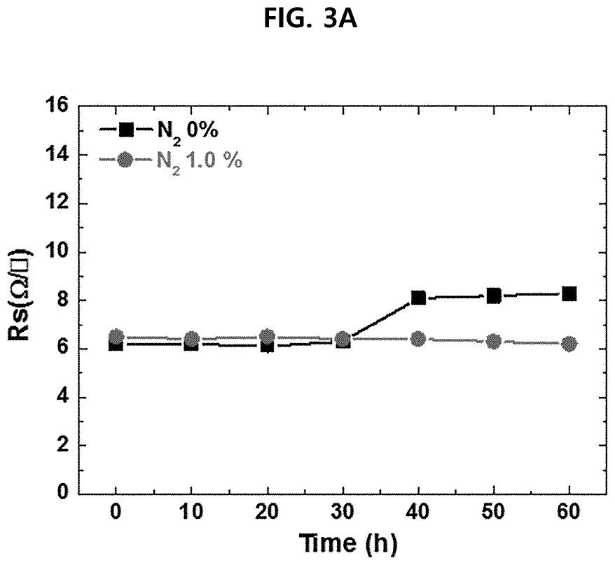

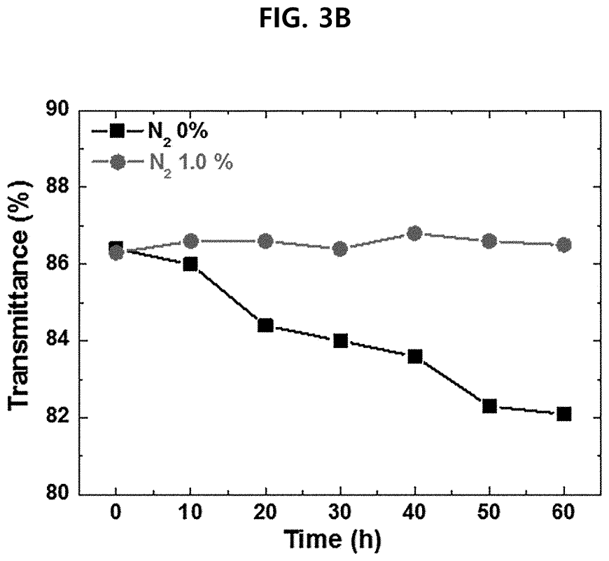

After the test, it can be seen from FIG. 3 that the characteristics are degraded after carrying out the constant temperature-constant humidity test for 10 hours, when the partial pressure of nitrogen is 0%. On the contrary, when the partial pressure of nitrogen is 1.0%, a low sheet resistance and high transmittance are maintained even after 60 hours.

Particularly, in the transparent thin film heater (Example 2) not doped with nitrogen, the electrical and optical properties start to be degraded 10 hours after the constant temperature-constant humidity test. On the contrary, the transparent thin film heater (Example 1) doped with nitrogen maintains the electrical and optical properties even after carrying out the constant temperature-constant humidity test for 60 hours, which suggests that doping with nitrogen improves the stability against high temperature and moisture.

### Test Example 2: Temperature Behavior

To apply electric voltage to the multilayered transparent conductive thin film obtained as described above, Ag was vapor-deposited to a thickness of 150 nm by using a two-terminal electrode as shown in FIG. 2 to obtain a multilayered transparent thin film heater.

The multilayered transparent thin film heater was fixed as shown in FIG. 2 in order to apply electric voltage thereto, a DC voltage supply was connected thereto, and then a thermocouple was attached to the center of the multilayered transparent thin film heater in order to measure the temperature thereof.

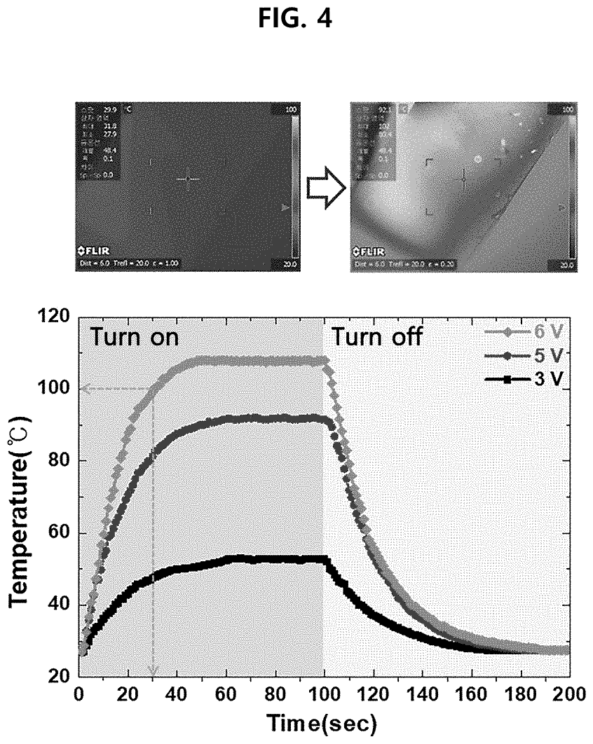

Referring to FIG. 4, it can be seen that the temperature of the transparent thin film heater is increased depending on the voltage applied thereto, after the temperature and response rate of the multilayered transparent thin film heater according to Example 1 were measured as a function of voltage. When a voltage of 6 V is applied, the temperature of the transparent thin film heater is increased rapidly, reaches 100° C. after 30 seconds, and is maintained stably after reaching the highest temperature of 110° C. In addition, it can be seen that the temperature is decreased to room temperature, when no voltage is applied.

### Test Example 3: Cycle Characteristics

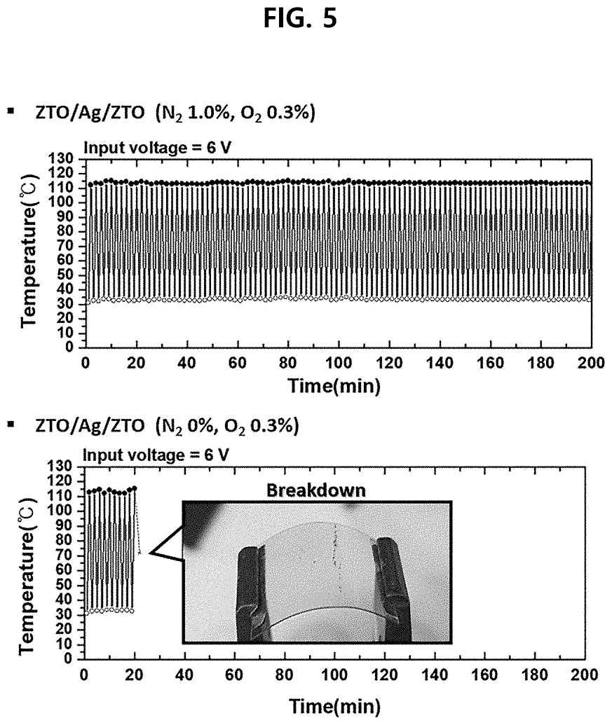

To determine the stability of the transparent thin film heater according to Example 1 of the present disclosure, a cycle test was carried out. The cycle test was carried out by measuring the temperature for 1 minute, when a voltage of 6 V was applied, and when no voltage was applied. This was taken as one cycle, and the test was performed for 100 cycles. The results are shown in FIG. 5.

Referring to FIG. 5, in the case of the Zn—SnOₓ/Ag/Zn—SnOₓ transparent thin film heater (Example 2) not doped with nitrogen, the transparent thin film heater was deteriorated after 10 cycles, and thus the temperature of the thin film cannot be measured. On the contrary, in the case of the Zn—SnOₓ/Ag/Zn—SnOₓ transparent thin film heater (Example 1) doped with nitrogen, the heater is operated well and stably even after 100 cycles.

### Test Example 4: Moisture Removal Test

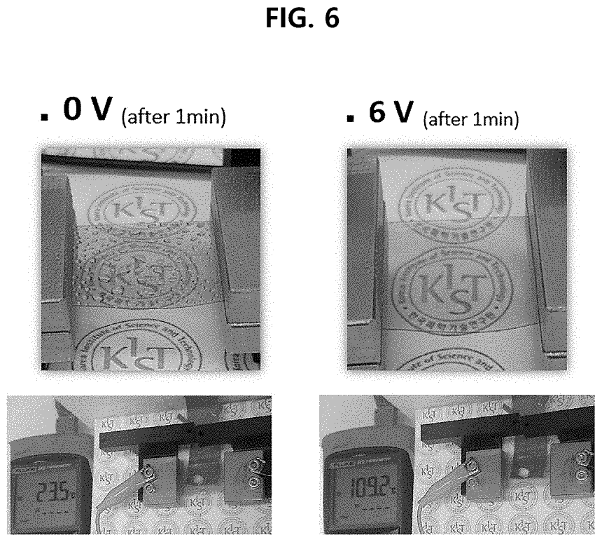

To carry out a moisture removal test for the Zn—SnOₓ/Ag/Zn—SnOₓ transparent thin film heater (Example 1) doped with nitrogen, water was sprayed to the thin film and a voltage of 6 V was applied thereto, as shown in FIG. 6. After the test, it can be seen that moisture is removed approximately 1 so minute after the voltage application.

Therefore, the multilayered transparent thin film heater including nitrogen-doped Zn—SnOₓ, which is determined to have excellent electrical and optical properties and to show moisture tolerance and thermal stability, has excellent cycle characteristics as well as a high response rate at a relatively low voltage, and thus can be applied to the field of smart widows for buildings, cars, or the like.

It should be understood that the above-described embodiments are given by way of illustration only and the scope of the present disclosure is not limited to the above detailed description. In addition, the scope of the present disclosure is defined by the following claims, and various changes, modifications and substitutions within the scope of the present disclosure will become apparent to those skilled in the art. Therefore, it is apparent to those skilled in the art that such modifications and changes fall within the scope of the present disclosure.

1. A transparent thin film heater comprising: a metal layer; and a transparent conductive oxide layer, wherein the transparent conductive oxide layer has a composition in which the following Chemical Formula 1 is doped with nitrogen:
ZnₓSn₁₋ₓO₂ [Chemical Formula 1]
wherein 0<x≤0.12.

2. The transparent thin film heater according to claim 1, which comprises a multilayer structure of transparent conductive oxide layer/metal layer/transparent conductive oxide layer OMO) or a multilayer structure of metal layer/transparent conductive oxide layer (MO).

3. The transparent thin film heater according to claim 1, wherein the metal layer has a thickness of 5-25 nm.

4. The transparent thin film heater according to claim 1, wherein the metal layer has a thickness of 8-15 nm.

5. The transparent thin film heater according to claim 1, wherein the transparent conductive oxide layer has a thickness of 20-80 nm.

6. The transparent thin film heater according to claim 1, wherein the transparent conductive oxide layer is formed through vapor deposition under gas atmosphere of argon (Ar), oxygen (O₂) and nitrogen (N₂).

7. The transparent thin film heater according to claim 1, wherein the transparent conductive oxide layer is doped with nitrogen under gas atmosphere with a partial pressure of nitrogen of 0.1-2.0%.

8. The transparent thin film heater according to claim 1, which is a flexible transparent thin film heater.

9. The transparent thin film heater according to claim 1, which further comprises a connection unit configured to apply electric voltage to the transparent thin film heater, and has an applied voltage of 1-10 V.

10. The transparent thin film heater according to claim 1, which reaches a temperature of 100° C. within 30 seconds, when a voltage of 6 V or less is applied thereto.

11. A transport means comprising the transparent thin film heater as defined in claim 1.

12. A smart window comprising the transparent thin film heater as defined in claim 1.

13. A method for manufacturing a transparent thin film heater, comprising a step of carrying out vapor deposition of a transparent conductive oxide layer on either surface or both surfaces of a metal layer, wherein the transparent conductive oxide layer has a composition in which the following Chemical Formula 1 is doped with nitrogen:
ZnₓSn₁₋ₓO₂ [Chemical Formula 1]
wherein 0<x≤0.12.

14. The method for manufacturing a transparent thin film heater according to claim 13, wherein the step of carrying out vapor deposition is performed under vapor deposition gas atmosphere comprising nitrogen (N₂); and at least one of argon (Ar) and oxygen (O₂).

15. The method for manufacturing a transparent thin film heater according to claim 13, wherein the vapor deposition is physical vapor deposition (PVD).

16. The method for manufacturing a transparent thin film heater according to claim 14, wherein the vapor deposition gas has a partial pressure represented by the following Mathematical Formulae 1 and 2:
[O₂/(Ar+O₂+N₂)]=X [Mathematical Formula 1]
[N₂/(Ar+O₂+N₂)]=Y [Mathematical Formula 2]
wherein 0<X≤0.01, and 0<Y<0.02.

17. The method for manufacturing a transparent thin film heater according to claim 14, wherein the vapor deposition gas has a partial pressure of nitrogen of 0.1-2.0%.

18. The method for manufacturing a transparent thin film heater according to claim 13, wherein the transparent conductive oxide layer is vapor-deposited on both surfaces of the metal layer on a substrate.

19. The method for manufacturing a transparent thin film heater according to claim 18, wherein the substrate is at least one selected from the group consisting of substrates including polyethylene terephthalate, polyether sulfone, polycarbonate or a polymer thereof.
